(19) United States
(12) Patent Application Publication
(10) Pub. No.: US 2025/0234625 A1
(43) Pub. Date: Jul. 17, 2025

(54) INTEGRATED CIRCUIT DEVICE

(71) Applicant: Samsung Electronics Co., Ltd., Suwon-si (KR)

(72) Inventors: Sangjine Park, Suwon-si (KR); Ilyoung Yoon, Suwon-si (KR)

(21) Appl. No.: 18/931,300

(22) Filed: Oct. 30, 2024

(30) Foreign Application Priority Data
Jan. 12, 2024 (KR) 10-2024-0005676

(51) Int. Cl. H01L 29/423; H01L 27/092; H01L 29/06; H01L 29/49; H01L 29/775; H01L 29/786

(52) U.S. Cl. CPC H10D 64/518; H10D 62/116; H10D 84/856; H10D 30/43; H10D 30/6735; H10D 30/6757; H10D 62/121; H10D 64/66

(57) ABSTRACT

An integrated circuit device includes a fin-type active region extending in a first horizontal direction on a substrate, a nanosheet stack including a plurality of nanosheets on the fin-type active region, a gate line extending around each of the plurality of nanosheets on the fin-type active region and extending in a second horizontal direction intersecting with the first horizontal direction, and a vertical structure at least partially overlapping the gate line in the second horizontal direction and including a side wall in contact with each of the plurality of nanosheets. The vertical structure further includes a recessed portion on the side wall thereof.

### CROSS-REFERENCE TO RELATED APPLICATION

This application is based on and claims priority under 35 U.S.C. § 119 to Korean Patent Application No. 10-2024-0005676, filed on Jan. 12, 2024, in the Korean Intellectual Property Office, the disclosure of which is incorporated by reference herein in its entirety.

### BACKGROUND

The inventive concept relates generally to an integrated circuit device, and more particularly, to an integrated circuit device including a field-effect transistor.

As the down-scaling of integrated circuit devices progresses rapidly, it is necessary to secure not only high-speed operation but also operational accuracy in integrated circuit devices. In addition, as the integration of integrated circuit devices increases and the size thereof decreases, the possibility of process defects occurring during a manufacturing process of nanosheet field-effect transistors may increase. Accordingly, it is necessary to develop integrated circuit devices having a new structure capable of eliminating (or reducing) the possibility of process defects and improving the performance and reliability of nanosheet field-effect transistors.

### SUMMARY

The inventive concept, as manifested by embodiments thereof, provides an integrated circuit device capable of providing stable performance and improved reliability in a nanosheet field-effect transistor.

According to an aspect of the inventive concept, there is provided an integrated circuit device including a fin-type active region extending in a first horizontal direction on a substrate, a nanosheet stack including a plurality of nanosheets arranged above the fin-type active region, a gate line surrounding (i.e., extending around) each of the plurality of nanosheets above the fin-type active region and extending in a second horizontal direction intersecting with the first horizontal direction, and a vertical structure at least partially overlapping the gate line in the second horizontal direction and including a side wall in contact with each of the plurality of nanosheets, wherein the vertical structure further includes a recessed portion on the side wall thereof.

According to another aspect of the inventive concept, there is provided an integrated circuit device including a substrate including a first region and a second region, a first fin-type active region extending in a first horizontal direction on the first region, a second fin-type active region extending in the first horizontal direction on the second region and apart from the first fin-type active region in a second horizontal direction intersecting with the first horizontal direction, a plurality of first nanosheets facing a top surface of the first fin-type active region at a position apart from the top surface of the first fin-type active region, a plurality of second nanosheets facing a top surface of the second fin-type active region at a position apart from the top surface of the second fin-type active region, a first gate line surrounding each of the plurality of first nanosheets above the first fin-type active region and extending in the second horizontal direction, a second gate line surrounding each of the plurality of second nanosheets above the second fin-type active region and extending in the second horizontal direction, and a vertical structure between the first gate line and the second gate line and having two side walls respectively in contact with each of the plurality of first nanosheets and each of the plurality of second nanosheets, wherein the two side walls of the vertical structure each include a recessed portion recessed into the vertical structure, and the first gate line and the second gate line each include a protruding portion extending into the recessed portion.

According to another aspect of the inventive concept, there is provided an integrated circuit device including a substrate including a first region and a second region, a first fin-type active region extending in a first horizontal direction on the first region, a second fin-type active region extending in the first horizontal direction on the second region and spaced apart from the first fin-type active region in a second horizontal direction intersecting with the first horizontal direction, a first nanosheet stack including a plurality of first nanosheets at different vertical levels each facing a top surface of the first fin-type active region at a position apart from the top surface of the first fin-type active region, a second nanosheet stack including a plurality of second nanosheets at different vertical levels, relative to an upper surface of the substrate as a reference layer, each facing a top surface of the second fin-type active region at a position apart from the top surface of the second fin-type active region, a first gate line surrounding each of the plurality of first nanosheets above the first fin-type active region and extending in the second horizontal direction, a second gate line surrounding each of the plurality of second nanosheets above the second fin-type active region and extending in the second horizontal direction, a vertical structure between the first gate line and the second gate line and in contact with each of the plurality of first nanosheets and each of the plurality of second nanosheets, a first source/drain region adjacent to the first gate line and in contact with each of the plurality of first nanosheets, and a second source/drain region adjacent to the second gate line and in contact with each of the plurality of second nanosheets, wherein the first gate line includes a first main metal layer, and a first work function metal layer between the first main metal layer and each of the plurality of first nanosheets and between the first main metal layer and the vertical structure, the second gate line includes a second main metal layer, and a second work function metal layer between the second main metal layer and each of the plurality of second nanosheets and between the second main metal layer and the vertical structure, the vertical structure includes an air space therein, the vertical structure further includes a first side wall and a second side wall, the first side wall facing the first gate line, and the second side wall facing the second gate line, the first side wall includes a first recessed portion, the second side wall includes a second recessed portion, the first work function metal layer includes a portion arranged in the first recessed portion and at least partially overlapping the vertical structure in a vertical direction, and the second work function metal layer includes a portion in the second recessed portion and at least partially overlapping the vertical structure in the vertical direction.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views.

FIG. 1 is a schematic plan layout diagram of some components of an integrated circuit device according to embodiments.

FIG. 2A is a schematic cross-sectional view of the integrated circuit device of FIG. 1, taken along line X1-X1.

FIG. 2B is a schematic cross-sectional view of the integrated circuit device of FIG. 1, taken along line Y1-Y1.

FIG. 3 is an enlarged schematic cross-sectional view of region EX1 of the integrated circuit device shown in FIG. 2B.

FIGS. 4 to 6 are enlarged schematic cross-sectional views of integrated circuit devices according to embodiments.

FIG. 7 is a schematic cross-sectional view of an integrated circuit device according to embodiments.

FIG. 8 is a schematic cross-sectional view of an integrated circuit device according to embodiments.

FIG. 9 is an enlarged schematic cross-sectional view of region EX2 of the integrated circuit device shown in FIG. 8.

FIGS. 10 and 11 are schematic cross-sectional views of integrated circuit devices according to embodiments.

FIGS. 12A to 12F are schematic cross-sectional views illustrating intermediate processes in an example method of manufacturing an integrated circuit device, according to embodiments.

FIGS. 13A and 13B are schematic cross-sectional views illustrating intermediate processes in an example method of manufacturing an integrated circuit device, according to embodiments.

### DETAILED DESCRIPTION

Hereinafter, embodiments are described in detail with reference to the accompanying drawings. The same reference numerals are used for the same components in the drawings, and redundant descriptions thereof are omitted.

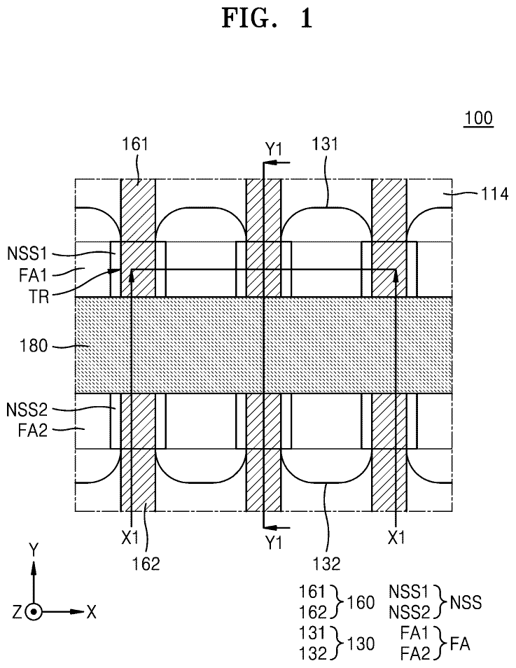

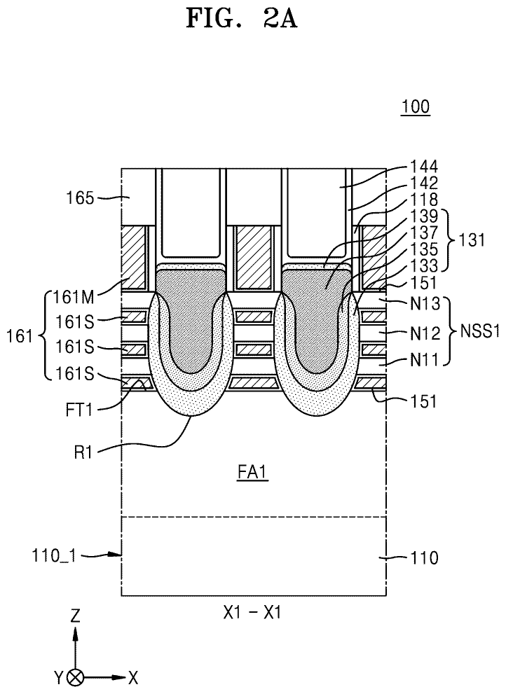

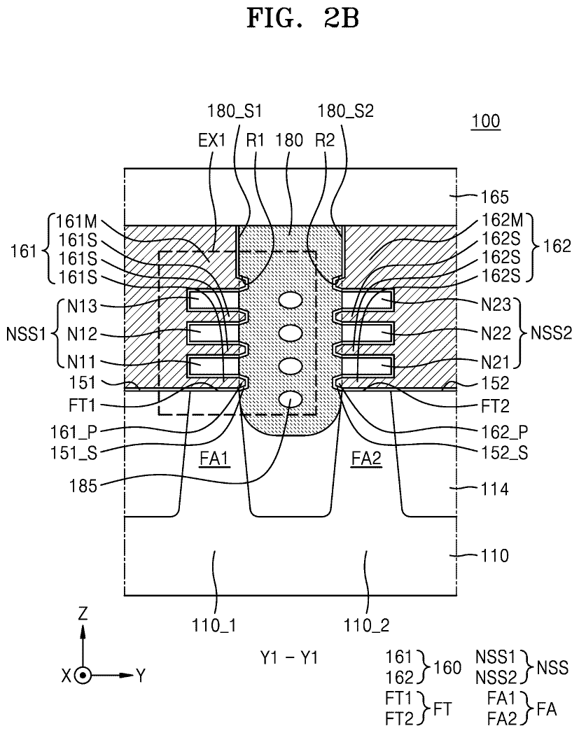

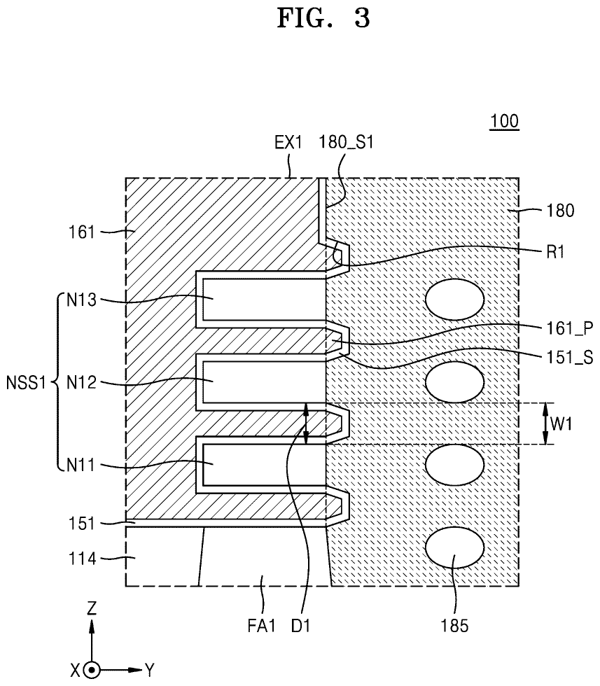

FIG. 1 is a schematic plan layout diagram of some components of an integrated circuit device 100 according to embodiments. FIG. 2A is a schematic cross-sectional view of the integrated circuit device 100, taken along line X1-X1 of FIG. 1. FIG. 2B is a schematic cross-sectional view of the integrated circuit device 100, taken along line Y1-Y1 of FIG. 1. FIG. 3 is an enlarged schematic cross-sectional view of region EX1 of FIG. 2B.

Hereinafter, referring to FIGS. 1, 2A, 2B, and 3, an integrated circuit device 100 including a field-effect transistor TR having a gate-all-around structure including an active region having the shape of a nanowire or nanosheet and a gate surrounding the active region is described. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

Referring to FIGS. 1, 2A, and 2B, the integrated circuit device 100 may include a plurality of fin-type active regions FA protruding (i.e., extending) upward from a substrate 110 in a vertical direction (a Z direction), perpendicular to an upper surface of the substrate 110, and extending lengthwise in a first horizontal direction (an X direction), parallel to the upper surface of the substrate 110, and a plurality of nanosheet stacks NSS arranged above the plurality of fin-type active regions FA. The term “nanosheet” as used herein refers to a conductive structure having a cross-section substantially perpendicular to a direction in which current flows. The “nanosheet” should be understood as including a nanowire.

The substrate 110 may include a semiconductor, such as silicon (Si) or germanium (Ge), or a compound semiconductor, such as SiGe, silicon carbide (SiC), gallium arsenide (GaAs), indium arsenide (InAs), indium gallium arsenide (InGaAs), or indium phosphide (InP). The terms “SiGe,” “SiC,” “GaAs,” “InAs,” “InGaAs,” and “InP” as used herein refer to materials including elements included in each term and are not chemical formulas representing a stoichiometric relationship. The substrate 110 may include a first region 110_1 and a second region 110_2 that are apart from each other in a second horizontal direction (a Y direction) parallel to the upper surface of the substrate 110 and intersecting with the first horizontal direction (the X direction).

In some embodiments, a first fin-type active region FA1 may be arranged on the first region 110_1 of the substrate 110. A second fin-type active region FA2 may be arranged on the second region 110_2 of the substrate 110. The first fin-type active region FA1 and the second fin-type active region FA2 may each extend in the first horizontal direction (the X direction) and may be spaced apart from each other in the second horizontal direction (the Y direction).

In some embodiments, a device isolation film 114 may be arranged on the substrate 110 to cover two side walls of each of the plurality of fin-type active regions FA. The term “cover” (or “covering,” “covers,” or like terms), as may be used herein, is intended to broadly refer to an element, structure or layer that is on or over another element, structure or layer, either directly or with one or more other intervening elements, structures or layers therebetween, and without requiring the element, structure or layer to entirely cover the other element, structure or layer. The device isolation film 114 may include an oxide film, a nitride film, or a combination thereof, although embodiments are not limited thereto.

In some embodiments, a plurality of gate lines 160 may be arranged above the plurality of fin-type active regions FA. The plurality of gate lines 160 may each extend lengthwise in the second horizontal direction (the Y direction).

In detail, the plurality of gate lines 160 may each include a first gate line 161 and a second gate line 162 that are spaced apart from each other in the second horizontal direction (the Y direction). The first gate line 161 may be arranged above the first fin-type active region FA1, above the first region 110_1 of the substrate 110. The second gate line 162 may be arranged above the second fin-type active region FA2, above the second region 1102 of the substrate 110.

In some embodiments, in regions in which the plurality of fin-type active regions FA and the plurality of gate lines 160 intersect with each other, a plurality of nanosheet stacks NSS may be arranged on a fin top surface FT of each of the plurality of fin-type active regions FA.

In detail, the plurality of nanosheet stacks NSS may include a first nanosheet stack NSS1 and a second nanosheet stack NSS2 that are spaced apart from each other in the second horizontal direction (the Y direction). The first nanosheet stack NSS1 may be arranged in a region in which the first fin-type active region FA1 and the first gate line 161 intersect with each other above the first region 110_1 of the substrate 110. The second nanosheet stack NSS2 may be arranged in a region in which the second fin-type active region FA2 and the second gate line 162 intersect with each other above the second region 110_2 of the substrate 110.

In some embodiments, a vertical structure 180 may be arranged between the first gate line 161 and the second gate line 162. The vertical structure 180 may be arranged between the first gate line 161 and the second gate line 162 in the second horizontal direction (the Y direction). The vertical structure 180 may extend in the first horizontal direction (the X direction) between the first gate line 161 and the second gate line 162. In some other embodiments, not explicitly shown, the vertical structure 180 may not extend in the first horizontal direction (the X direction) between the first gate line 161 and the second gate line 162 and may be arranged only between the first gate line 161 and the second gate line 162.

In some embodiments, the vertical structure 180 may have a top surface arranged at the same vertical level as top surfaces of the first gate line 161 and the second gate line 162, relative to the upper surface of the substrate 110 as a reference layer. The vertical structure 180 may include a portion arranged between the first fin-type active region FA1 and the second fin-type active region FA2 in the second horizontal direction (Y direction).

In some embodiments, the device isolation film 114 may be arranged below the vertical structure 180 to completely fill a space between the first fin-type active region FA1 and the second fin-type active region FA2. The term “fill” (or “filling,” “filled,” or like terms), as may be used herein, is intended to refer broadly to either completely filling a defined space (e.g., the space between the first fin-type active region FA1 and the second fin-type active region FA2) or partially filling the defined space; that is, the defined space need not be entirely filled but may, for example, be partially filled or have voids or other spaces throughout. In some other embodiments, not explicitly shown, the device isolation film 114 may not be arranged below the vertical structure 180, and the vertical structure 180 may extend further in a vertical downward direction (a −Z direction). In some other embodiments, not explicitly shown, the device isolation film 114 may not be arranged below the vertical structure 180, and the first fin-type active region FA1 and the second fin-type active region FA2 may be connected to each other and arranged below the vertical structure 180.

In some embodiments, the vertical structure 180 may be in contact with each of the plurality of nanosheet stacks NSS. The term “contact” (or “contacting,” or like terms, such as “connect” or “connecting”), as may be used herein, is intended to refer to physical and/or electrical contact between two or more elements, and may include other intervening elements. As used herein, the term “and/or” includes any and all combinations of one or more of the associated listed items. In detail, the vertical structure 180 may be in contact with the first nanosheet stack NSS1 and the second nanosheet stack NSS2 and may be arranged between the first nanosheet stack NSS1 and the second nanosheet stack NSS2. For example, the first nanosheet stack NSS1 and the second nanosheet stack NSS2 may be spaced apart from each other with the vertical structure 180 therebetween.

In some embodiments, the vertical structure 180 may include an air space 185 therein. For example, the vertical structure 180 may include one or more air spaces 185 therein. The air space 185 is described in detail below with reference to FIG. 3.

In some embodiments, the plurality of nanosheet stacks NSS may each include at least one nanosheet facing the fin top surface FT of the fin-type active region FA at a position apart from the fin top surface FT in the vertical direction (the Z direction). In detail, the first nanosheet stack NSS1 may include at least one nanosheet facing a first fin top surface FT1 of the first fin-type active region FA1 at a position apart from the first fin top surface FT1 in the vertical direction (the Z direction). In detail, the second nanosheet stack NSS2 may include at least one nanosheet facing a second fin top surface FT2 of the second fin-type active region FA2 at a position apart from the second fin top surface FT2 in the vertical direction (the Z direction).

As illustrated in FIGS. 2A and 2B, the first nanosheet stack NSS1 may include a first nanosheet N11, a second nanosheet N12, and a third nanosheet N13 that overlap each other in the vertical direction (the Z direction) above the first fin-type active region FA1. The term “overlap” (or “overlapping,” or like terms), as may be used herein, is intended to broadly refer to a first element that intersects with at least a portion of a second element in the vertical direction (i.e., the Z direction), but does not require that the first and second elements be completely aligned with one another in a horizontal plane (i.e., in the first horizontal direction and/or the second horizontal direction). The first nanosheet N11, the second nanosheet N12, and the third nanosheet N13 may have different vertical distances (Z direction distances) from the first fin top surface FT1 of the first fin-type active region FA1.

Likewise, the second nanosheet stack NSS2 may include a first nanosheet N21, a second nanosheet N22, and a third nanosheet N23 that overlap each other in the vertical direction (the Z direction) above the second fin-type active region FA2. The first nanosheet N21, the second nanosheet N22, and the third nanosheet N23 may have different vertical distances (Z direction distances) from the second fin top surface FT2 of the second fin-type active region FA2.

Although FIGS. 2A and 2B illustrate a case in which the plurality of nanosheet stacks NSS each include three nanosheets, the inventive concept is not limited thereto, and the plurality of nanosheet stacks NSS may each include four or more nanosheets or less than three nanosheets.

Although FIG. 1 illustrates a case in which the nanosheet stack NSS has an approximately quadrangular planar shape, embodiments are not limited thereto. The nanosheet stack NSS may have various planar shapes depending on a planar shape of each of the fin-type active region FA and the gate line 160. Herein, a configuration in which a plurality of nanosheet stacks NSS and a plurality of gate lines 160 are arranged above one fin-type active region FA, and the plurality of nanosheet stacks NSS are arranged in a row in the first horizontal direction (the X direction) above the one fin-type active region FA is described. However, the numbers of nanosheet stacks NSS and gate lines 160 arranged on one fin-type active region FA are not particularly limited.

In some embodiments, the first nanosheet N11, the second nanosheet N12, and the third nanosheet N13 included in the first nanosheet stack NSS1 may each include a channel region. Herein, the first nanosheet N11, the second nanosheet N12, and the third nanosheet N13 may each be referred to as a channel region. In some embodiments, the first nanosheet N11, the second nanosheet N12, and the third nanosheet N13 may each have a cross-sectional thickness in a range of about 4 nm to about 6 nm, but embodiments are not limited thereto. Here, the thickness of each of the first nanosheet N11, the second nanosheet N12, and the third nanosheet N13 refers to the size thereof in the vertical direction (the Z direction). In some embodiments, the first nanosheet N11, the second nanosheet N12, and the third nanosheet N13 may have substantially the same thickness in the vertical direction (the Z direction). In some other embodiments, at least some of the first nanosheet N11, the second nanosheet N12, and the third nanosheet N13 may have different thicknesses in the vertical direction (the Z direction).

In some embodiments, the same may also apply to the first nanosheet N21, the second nanosheet N22, and the third nanosheet N23 included in the second nanosheet stack NSS2. For example, the first nanosheet N21, the second nanosheet N22, and the third nanosheet N23 may each be referred to as a channel region.

In some embodiments, at least some of the first nanosheet N11, the second nanosheet N12, and the third nanosheet N13 included in the first nanosheet stack NSS1 may have different sizes in the first horizontal direction (the X direction). In some other embodiments, at least some of the first nanosheet N11, the second nanosheet N12, and the third nanosheet N13 may have the same size in the first horizontal direction (the X direction). In some embodiments, the same may also apply to the first nanosheet N21, the second nanosheet N22, and the third nanosheet N23 included in the second nanosheet stack NSS2.

In some embodiments, the plurality of nanosheets may each be in contact with the vertical structure 180. In detail, the first nanosheet N11, the second nanosheet N12, and the third nanosheet N13 included in the first nanosheet stack NSS1 may be in contact with the vertical structure 180. In detail, the first nanosheet N21, the second nanosheet N22, and the third nanosheet N23 included in the second nanosheet stack NSS2 may be in contact with the vertical structure 180.

As described above, as the vertical structure 180 is arranged in contact with the plurality of nanosheets, the plurality of gate lines 160 may not extend further in the second horizontal direction (the Y direction) than the plurality of nanosheets. In detail, as the vertical structure 180 is arranged in contact with the first nanosheet N11, the second nanosheet N12, and the third nanosheet N13 included in the first nanosheet stack NSS1, the first gate line 161 may not extend further in the second horizontal direction (the Y direction) toward the second fin-type active region FA2 than the first nanosheet N11, the second nanosheet N12, and the third nanosheet N13 included in the first nanosheet stack NSS1. In detail, as the vertical structure 180 is arranged in contact with the first nanosheet N21, the second nanosheet N22, and the third nanosheet N23 included in the second nanosheet stack NSS2, the second gate line 162 may not extend further in the second horizontal direction (the Y direction) toward the first fin-type active region FA1 than the first nanosheet N21, the second nanosheet N22, and the third nanosheet N23 included in the second nanosheet stack NSS2.

As illustrated in FIGS. 2A and 2B, the plurality of gate lines 160 may each include a main gate portion and a plurality of sub-gate portions. In detail, the first gate line 161 may include a first main gate portion 161M and a plurality of first sub-gate portions 161S. The first main gate portion 161M may cover a top surface of the first nanosheet stack NSS1 and may extend in the second horizontal direction (the Y direction). The plurality of first sub-gate portions 161S may be integrally connected to the first main gate portion 161M and may be arranged one each between the first nanosheet N11 and the second nanosheet N12, between the second nanosheet N12 and the third nanosheet N13, and between the first nanosheet N11 and the first fin-type active region FA1. In the vertical direction (the Z direction), a thickness of each of the plurality of first sub-gate portions 161S may be less than a thickness of the first main gate portion 161M.

Likewise, the second gate line 162 may include a second main gate portion 162M and a plurality of second sub-gate portions 162S. The second main gate portion 162M may cover a top surface of the second nanosheet stack NSS2 and may extend in the second horizontal direction (the Y direction). The plurality of second sub-gate portions 162S may be integrally connected to the second main gate portion 162M and may be arranged one each between the first nanosheet N21 and the second nanosheet N22, between the second nanosheet N22 and the third nanosheet N23, and between the first nanosheet N21 and the second fin-type active region FA2. In the vertical direction (the Z direction), a thickness of each of the plurality of second sub-gate portions 162S may be less than a thickness of the second main gate portion 162M.

The plurality of gate lines 160 may each include metal, metal nitride, metal carbide, or a combination thereof, although embodiments are not limited thereto. The metal may be selected from, for example, titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysosium (Dy), erbium (Er), and palladium (Pd). The metal nitride may be selected from titanium nitride (TiN) and tantalum nitride (TaN). The metal carbide may be titanium aluminum carbide (TiAlC). However, materials constituting the plurality of gate lines 160 are not limited to the above examples.

First and second gate dielectric films 151 and 152 may be arranged between the nanosheet stack NSS and the gate line 160 and between the gate line 160 and the vertical structure 180. In detail, the first gate dielectric film 151 may be arranged between the first nanosheet stack NSS1 and the first gate line 161 and between the first gate line 161 and the vertical structure 180. For example, the first gate dielectric film 151 may be arranged between each of the first nanosheet N11, the second nanosheet N12, and the third nanosheet N13 included in the first nanosheet stack NSS1 and the first gate line 161, between the first main gate portion 161M and the vertical structure 180, and between the plurality of first sub-gate portions 161S and the vertical structure 180. In detail, the second gate dielectric film 152 may be arranged between the second nanosheet stack NSS2 and the second gate line 162 and between the second gate line 162 and the vertical structure 180. For example, the second gate dielectric film 152 may be arranged between each of the first nanosheet N21, the second nanosheet N22, and the third nanosheet N23 included in the second nanosheet stack NSS2 and the second gate line 162, between the second main gate portion 162M and the vertical structure 180, and between the plurality of second sub-gate portions 162S and the vertical structure 180.

In some embodiments, above the fin-type active region FA, a pair of source/drain regions 130 may be respectively arranged on two sides of one gate line 160 with the gate line 160 therebetween. In detail, above the first fin-type active region FA1, a pair of first source/drain regions 131 may be respectively arranged on two sides of the first gate line 161 with the first gate line 161 therebetween. One first source/drain region 131 may be arranged on the first fin-type active region FA1 between a pair of first nanosheet stacks NSS1 adjacent to each other. The first source/drain region 131 may be in contact with a side wall of the first nanosheet stack NSS1 surrounded by the first gate line 161 adjacent thereto. Likewise, above the second fin-type active region FA2, a pair of second source/drain regions 132 may be respectively arranged on two sides of the second gate line 162 with the second gate line 162 therebetween. One second source/drain region 132 may be arranged on the second fin-type active region FA2 between a pair of second nanosheet stacks NSS2 adjacent to each other. The second source/drain region 132 may be in contact with a side wall of the second nanosheet stack NSS2 surrounded by the second gate line 162 adjacent thereto.

In some embodiments, two side walls (i.e., opposing sidewalls) of each of the plurality of gate lines 160 may be covered with an outer insulating spacer 118. In detail, two side walls (opposing sidewalls) of the first gate line 161 may be covered with the outer insulating spacer 118. The outer insulating spacer 118 may cover two side walls of the first main gate portion 161M on the top surface of the first nanosheet stack NSS1. The outer insulating spacer 118 may be apart from the first gate line 161 with the first gate dielectric film 151 therebetween. The outer insulating spacer 118 may include silicon nitride, silicon oxide, SiCN, SiBN, SiON, SiOCN, SiBCN, SiOC, or a combination thereof. The terms “SiCN,” “SiBN,” “SiON,” “SiOCN,” “SiBCN,” and “SiOC” as used herein refer to materials including elements included in each term and are not chemical formulas representing a stoichiometric relationship. Although not illustrated, the same may also apply to the second gate line 162.

In some embodiments, a plurality of source/drain regions 130 may each include a portion overlapping the outer insulating spacer 118 in the vertical direction (the Z direction). For example, the first source/drain region 131 may include a portion overlapping the outer insulating spacer 118 in the vertical direction (the Z direction). In some embodiments, the plurality of source/drain regions 130 may not each include a portion overlapping the main gate portion in the vertical direction (the Z direction). For example, the first source/drain region 131 may not include a portion overlapping the first main gate portion 161M in the vertical direction (the Z direction). Although not illustrated, the same may also apply to the second source/drain region 132.

In some embodiments, two side walls of each of the plurality of sub-gate portions may be apart from the source/drain region 130 with a gate dielectric film therebetween. For example, two side walls of each of the plurality of first sub-gate portions 161S may be apart from the first source/drain region 131 with the first gate dielectric film 151 therebetween. The gate dielectric film may include a portion in contact with a first semiconductor layer of the source/drain region 130. For example, the first gate dielectric film 151 may include a portion in contact with a first semiconductor layer 133 of the first source/drain region 131. Although not illustrated, the same may also apply to the second source/drain region 132.

In some embodiments, a plurality of source/drain regions 130 may be arranged on the fin-type active region FA. A vertical level of the bottommost surface of each of the plurality of source/drain regions 130 may be lower than a vertical level of the fin top surface FT of the fin-type active region FA, relative to the upper surface of the substrate 110 as a reference layer. In detail, a plurality of first source/drain regions 131 may each be arranged adjacent to at least one first gate line 161 selected from among a plurality of first gate lines 161. The plurality of first source/drain regions 131 may each have a side wall facing the first nanosheet N11, the second nanosheet N12, and the third nanosheet N13 included in the first nanosheet stack NSS1 adjacent thereto. The plurality of first source/drain regions 131 may each be in contact with the first nanosheet N11, the second nanosheet N12, and the third nanosheet N13 included in the first nanosheet stack NSS1 adjacent thereto. The plurality of first source/drain regions 131 may have bottom surfaces in contact with a plurality of first fin-type active regions FA1. Although not illustrated, the same may also apply to the second source/drain region 132.

In some embodiments, the plurality of source/drain regions 130 may include a plurality of semiconductor layers. In detail, the plurality of semiconductor layers included in the first source/drain region 131 may include the first semiconductor layer 133, a second semiconductor layer 135 formed on the first semiconductor layer 133, and a third semiconductor layer 137 formed on the second semiconductor layer 135. In some embodiments, the plurality of semiconductor layers may further include a capping layer 139 formed on the third semiconductor layer 137. Although not illustrated, the same may also apply to the second source/drain region 132.

In some embodiments, in each of the plurality of first source/drain regions 131, the first semiconductor layer 133 may include a portion in contact with a channel region and a portion in contact with the first fin-type active region FA1. That is, the first semiconductor layer 133 may include a portion in contact with the first nanosheet N11, the second nanosheet N12, and the third nanosheet N13, a portion in contact with the plurality of first sub-gate portions 161S, and a portion in contact with the first fin-type active region FA1. Although not illustrated, the same may also apply to the second source/drain region 132.

In some embodiments, a top surface of each of the first and second gate dielectric films 151 and 152, the gate line 160, and the outer insulating spacer 118 may be covered with a capping insulating pattern 165. The capping insulating pattern 165 may include a silicon nitride film.

In some embodiments, a plurality of outer insulating spacers 118 and the plurality of source/drain regions 130 may be covered with an insulating liner 142. The insulating liner 142 may include silicon nitride (SiN), silicon oxide (SiO), SiCN, SiBN, SiON, SiOCN, SiBCN, SiOC, or a combination thereof. In some embodiments, the insulating liner 142 may be omitted. An inter-gate insulating film 144 may be arranged on the insulating liner 142. The inter-gate insulating film 144 may include a silicon nitride film, a silicon oxide film, SiON, SiOCN, or a combination thereof. When the insulating liner 142 is omitted, the inter-gate insulating film 144 may be in contact with the plurality of source/drain regions 130.

As illustrated in FIG. 1, a plurality of field-effect transistors TR may be formed in portions on the substrate 110 in which the plurality of fin-type active regions FA and the plurality of gate lines 160 intersect with each other. The plurality of field-effect transistors TR may constitute a logic circuit or memory device.

Referring to FIGS. 2B and 3 together, the vertical structure 180 may include a first side wall 180_S1 facing the first gate line 161, and a second side wall 180_S2 facing the second gate line 162. The first side wall 180_S1 is laterally opposite the second side wall 180_S2 (i.e., in the second horizontal direction).

In some embodiments, the first side wall 180_S1 may include a first recessed portion R1 recessed into the vertical structure 180. The second side wall 180_S2 may include a second recessed portion R2 recessed into the vertical structure 180. The first recessed portion R1 and the second recessed portion R2 may (for example, at least partially) overlap the vertical structure 180 in the vertical direction (the Z direction).

In some embodiments, a portion of the first gate dielectric film 151 and a portion of the first gate line 161 may be arranged in the first recessed portion R1. In detail, the first gate dielectric film 151 may include a sub-portion 151_S arranged in the first recessed portion R1. In detail, the first gate line 161 may include a first protruding portion 161_P arranged in the first recessed portion R1. The first gate line 161 may include the first protruding portion 161_P protruding (i.e., extending horizontally) into the first recessed portion R1. For example, the first main gate portion 161M of the first gate line 161 may include the first protruding portion 161_P protruding into the first recessed portion R1. For example, each of the plurality of first sub-gate portions 161S of the first gate line 161 may include the first protruding portion 161_P protruding into the first recessed portion R1. For example, some of the plurality of first sub-gate portions 161S of the first gate line 161 may include the first protruding portion 161_P protruding into the first recessed portion R1.

In some embodiments, the sub-portion 151_S of the first gate dielectric film 151 may (for example, at least partially) overlap the vertical structure 180 in the vertical direction (the Z direction). In some embodiments, the first protruding portion 161_P of the first gate line 161 may (for example, at least partially) overlap the vertical structure 180 in the vertical direction (the Z direction).

Likewise, a portion of the second gate dielectric film 152 and a portion of the second gate line 162 may be arranged in the second recessed portion R2. In detail, the second gate dielectric film 152 may include a sub-portion 152_S arranged in the second recessed portion R2. In detail, the second gate line 162 may include a second protruding portion 162_P arranged in the second recessed portion R2. The second gate line 162 may include the second protruding portion 162_P protruding (i.e., extending horizontally) into the second recessed portion R2. For example, each of the second main gate portion 162M and the plurality of second sub-gate portions 162S of the second gate line 162 may include the second protruding portion 162_P protruding into the second recessed portion R2.

In some embodiments, the sub-portion 152_S of the second gate dielectric film 152 may (for example, at least partially) overlap the vertical structure 180 in the vertical direction (the Z direction). In some embodiments, the second protruding portion 162_P of the second gate line 162 may (for example, at least partially) overlap the vertical structure 180 in the vertical direction (the Z direction).

As illustrated in FIGS. 2B and 3, the first recessed portion R1 and the second recessed portion R2 may each have two side walls that are not parallel to each other and a bottom surface that is substantially parallel to a side wall of the vertical structure 180. Accordingly, the first protruding portion 161_P and the second protruding portion 162_P respectively arranged in the first recessed portion R1 and the second recessed portion R2 may each have a quadrangular shape. For example, the first protruding portion 161_P and the second protruding portion 162_P may each have a trapezoidal shape.

As illustrated in FIG. 3, the first recessed portion R1 may have a first width W1 in the vertical direction (the Z direction). In detail, an opening of the first recessed portion R1 may have the first width W1 in the vertical direction (the Z direction). For example, the first width W1 of the first recessed portion R1 may be a width of a portion of the first recessed portion R1 having the largest width in the vertical direction (the Z direction).

In some embodiments, the first width W1 of the first recessed portion R1 may be equal to or less than a distance between two adjacent nanosheets among the plurality of nanosheets of the first nanosheet stack NSS1. For example, the first width W1 of the first recessed portion R1 may be equal to or less than a first distance D1 between two adjacent nanosheets, for example, the first nanosheet N11 and the second nanosheet N12. In other words, the first recessed portion R1 may be arranged between two adjacent nanosheets. For example, the first recessed portion R1 may not overlap two adjacent nanosheets in the second horizontal direction (the Y direction). Herein, two nanosheets adjacent to the first recessed portion R1 may refer to two nanosheets that are adjacent to the first recessed portion R1 in the vertical direction (the Z direction).

In some embodiments, the sub-portion 151_S of the first gate dielectric film 151 and the first protruding portion 161_P of the first gate line 161, which are arranged in the first recessed portion R1, may be arranged between two adjacent nanosheets. For example, the sub-portion 151_S of the first gate dielectric film 151 and the first protruding portion 161_P of the first gate line 161 may not overlap two adjacent nanosheets in the second horizontal direction (the Y direction).

Likewise, a width of the second recessed portion R2 in the vertical direction (the Z direction), that is, a width of an opening of the second recessed portion R2 in the vertical direction (the Z direction), may be equal to or less than a distance between two adjacent nanosheets among the plurality of nanosheets of the second nanosheet stack NSS2. For example, the second recessed portion R2 may not overlap two adjacent nanosheets in the second horizontal direction (the Y direction).

In some embodiments, the sub-portion 152_S of the second gate dielectric film 152 and the second protruding portion 162_P of the second gate line 162, which are arranged in the second recessed portion R2, may be arranged between two adjacent nanosheets. For example, the sub-portion 152_S of the second gate dielectric film 152 and the second protruding portion 162_P of the second gate line 162, which are arranged in the second recessed portion R2, may not overlap two adjacent nanosheets in the second horizontal direction (the Y direction).

As illustrated in FIGS. 2B and 3, the vertical structure 180 may further include the air space 185 therein. For example, the vertical structure 180 may further include one or more air spaces 185.

In some embodiments, the air space 185 may overlap the plurality of nanosheets in the second horizontal direction (the Y direction). In detail, the air space 185 may at least partially overlap the plurality of nanosheets of the first nanosheet stack NSS1 in the second horizontal direction (the Y direction). For example, a plurality of air spaces 185 may respectively overlap the first nanosheet N11, the second nanosheet N12, and the third nanosheet N13 of the first nanosheet stack NSS1 in the second horizontal direction (the Y direction). The air space 185 may overlap the plurality of nanosheets of the second nanosheet stack NSS2 in the second horizontal direction (the Y direction). For example, a plurality of air spaces 185 may respectively overlap the first nanosheet N21, the second nanosheet N22, and the third nanosheet N23 of the second nanosheet stack NSS2 in the second horizontal direction (the Y direction).

In some embodiments, the air space 185 may overlap a top portion of the first fin-type active region FA1 in the second horizontal direction (the Y direction). For example, some of the plurality of air spaces 185 may overlap the top portion of the first fin-type active region FA1 in the second horizontal direction (the Y direction). In some embodiments, the air space 185 may overlap a top portion of the second fin-type active region FA2 in the second horizontal direction (the Y direction). For example, some of the plurality of air spaces 185 may overlap the top portion of the second fin-type active region FA2 in the second horizontal direction (the Y direction).

In some embodiments, the air space 185 may include a portion that does not overlap the first recessed portion R1 in the second horizontal direction (the Y direction). For example, each of the plurality of air spaces 185 may include a portion that does not overlap the first recessed portion R1 adjacent thereto in the second horizontal direction (the Y direction). In some embodiments, the air space 185 may include a portion that does not overlap the second recessed portion R2 in the second horizontal direction (the Y direction). For example, each of the plurality of air spaces 185 may include a portion that does not overlap the second recessed portion R2 adjacent thereto in the second horizontal direction (the Y direction). Herein, the first recessed portion R1 and the second recessed portion R2 that are adjacent to the air space 185 may refer to the first recessed portion R1 and the second recessed portion R2 that are adjacent to the air space 185 in the vertical direction (the Z direction).

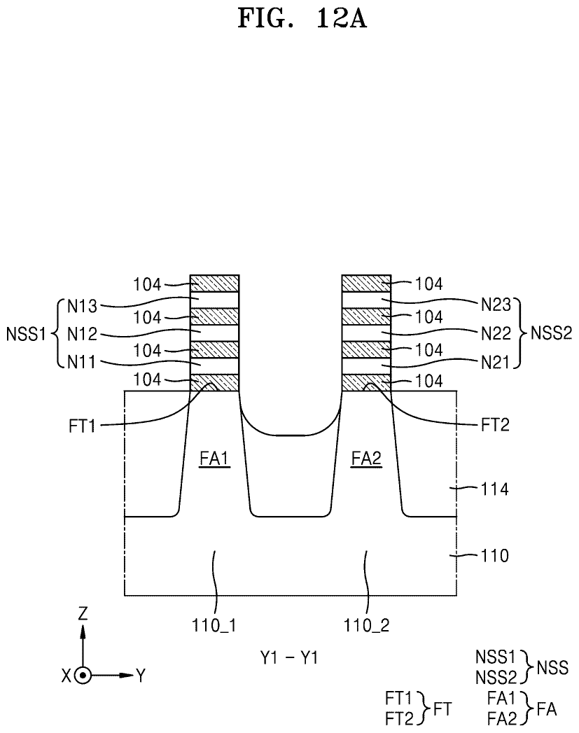

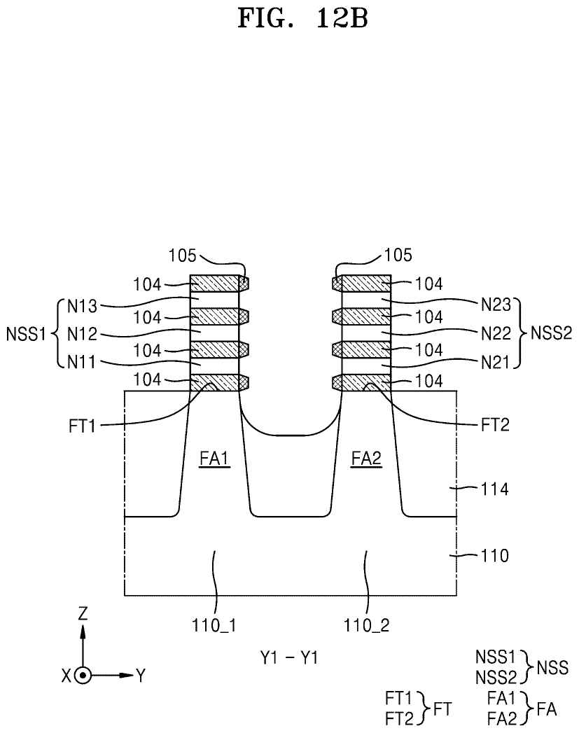

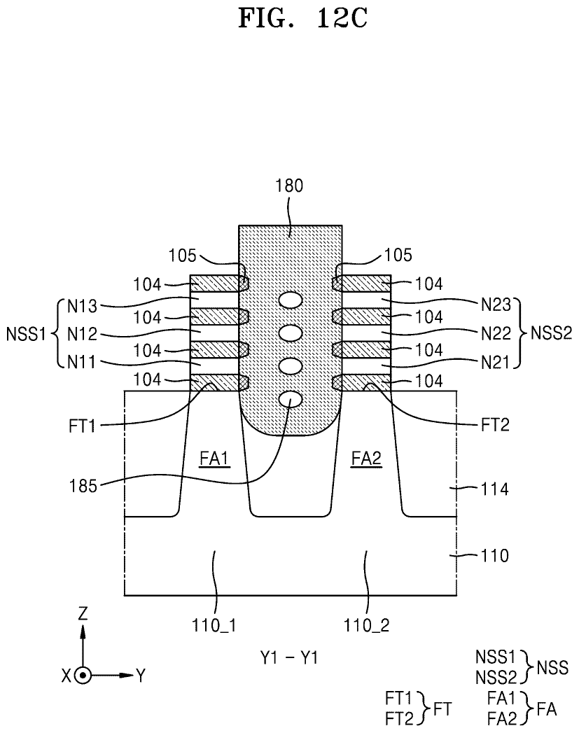

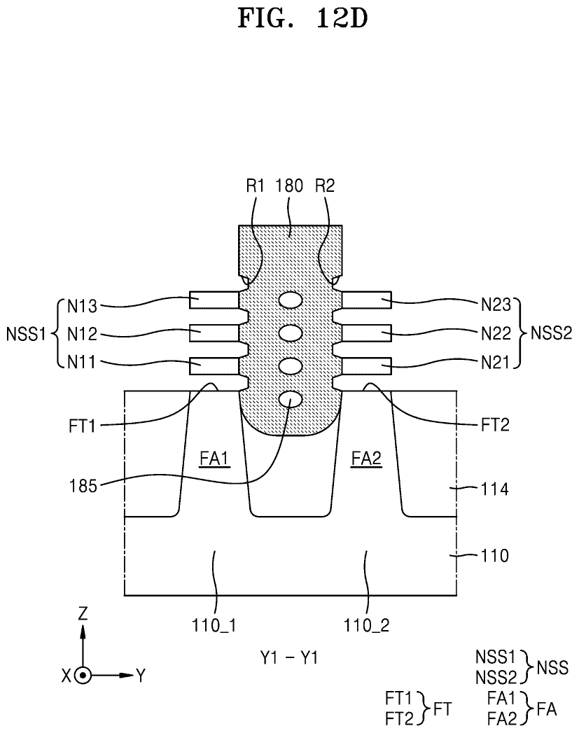

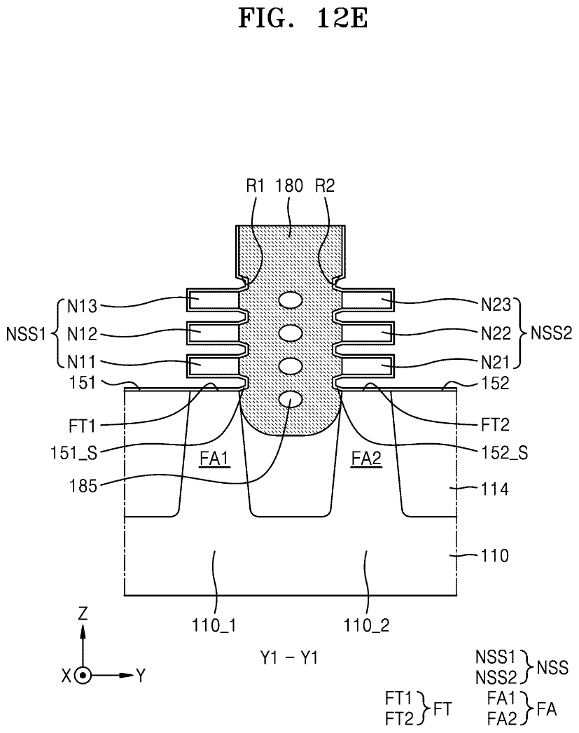

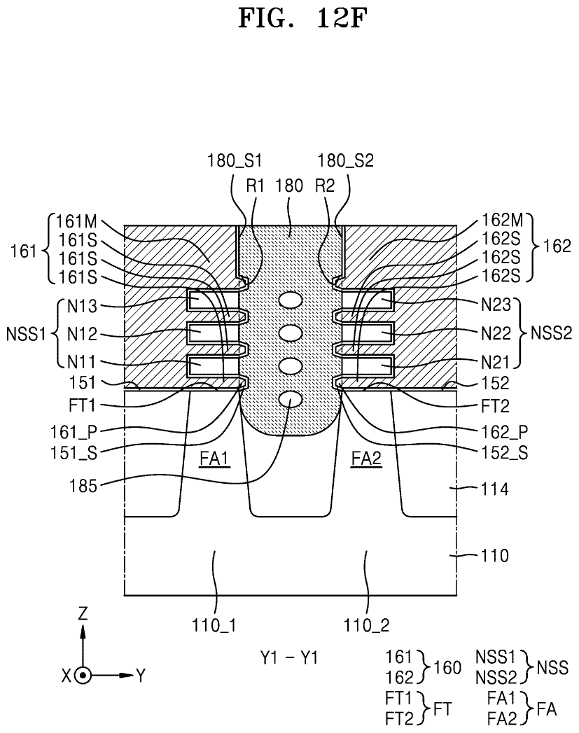

In some embodiments, the air space 185 arranged in the vertical structure 180 may be created by the first and second recessed portions R1 and R2 on two side walls of the vertical structure 180. This aspect is described in detail below with reference to FIGS. 12A to 12F.

According to the inventive concept, the integrated circuit device 100 including the vertical structure 180 including the first and second recessed portions R1 and R2 on the side walls thereof may be provided. As portions of the first and second gate dielectric films 151 and 152 and the first and second gate lines 161 and 162 are respectively arranged in the first and second recessed portions R1 and R2 of the integrated circuit device 100, an effective channel width may increase. That is, according to the inventive concept, the integrated circuit device 100 having improved performance and reliability may be provided.

According to the inventive concept, the integrated circuit device 100 including the vertical structure 180 including one or more air spaces 185 therein may be provided. As the vertical structure 180 includes one or more air spaces 185 therein, parasitic capacitance may be reduced. That is, according to the inventive concept, the integrated circuit device 100 having improved performance and reliability may be provided.

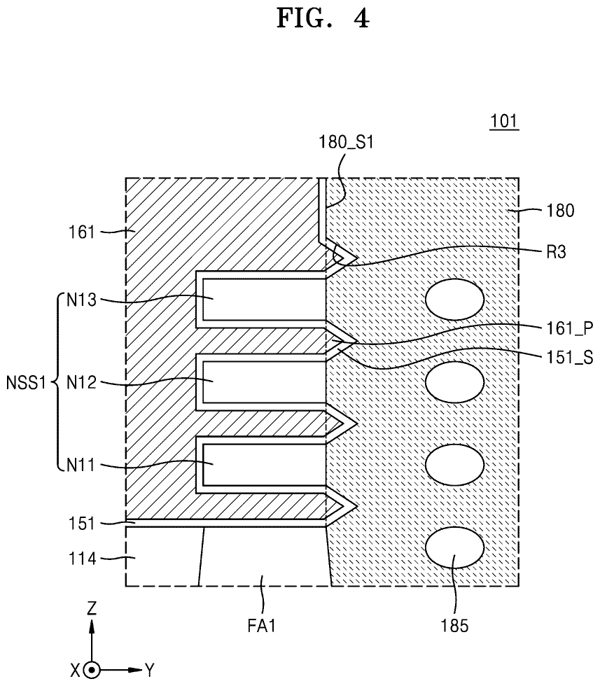

FIGS. 4 to 6 are enlarged schematic cross-sectional views of integrated circuit devices 101, 102, and 103, respectively, according to embodiments. In detail, FIGS. 4 to 6 are enlarged schematic cross-sectional views of a portion corresponding to the region EX1 of integrated circuit device 100 shown in FIG. 2B. Hereinafter, the differences from the integrated circuit device 100 described with reference to FIGS. 1, 2A, 2B, and 3 are mainly described.

Referring to FIG. 4, the integrated circuit device 101 may include the vertical structure 180 in contact with the plurality of nanosheets. The vertical structure 180 may include one or more air spaces 185 therein. The vertical structure 180 may include a third recessed portion R3 on a side wall thereof facing the plurality of nanosheets.

In some embodiments, the third recessed portion R3 of the integrated circuit device 101 may include an opening and two side walls that are not parallel to each other. For example, the third recessed portion R3 may have a triangular shape. Accordingly, the first protruding portion 161_P of the first gate line 161 in the third recessed portion R3 may have a triangular shape.

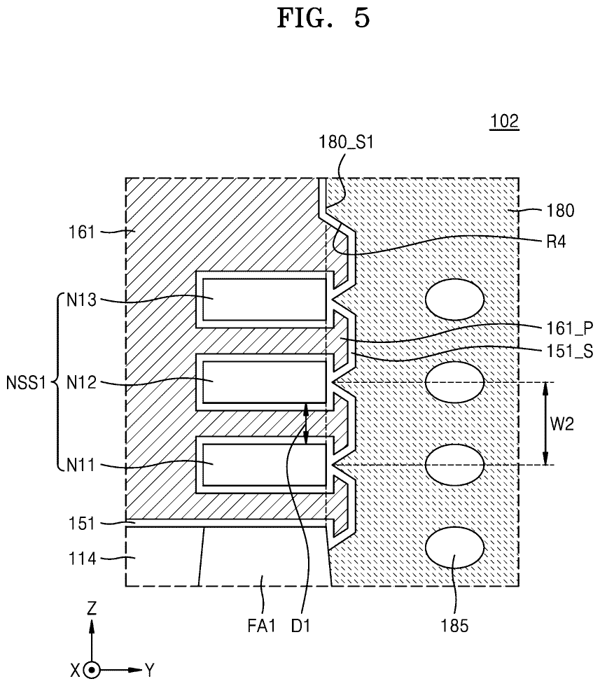

Referring to FIG. 5, the integrated circuit device 102 may include the vertical structure 180 in contact with the plurality of nanosheets. The vertical structure 180 may include one or more air spaces 185 therein. The vertical structure 180 may include a fourth recessed portion R4 on a side wall thereof facing the plurality of nanosheets.

In some embodiments, the fourth recessed portion R4 of the integrated circuit device 102 may have a second width W2 in the vertical direction (the Z direction). In detail, an opening of the fourth recessed portion R4 may have the second width W2 in the vertical direction (the Z direction). For example, the second width W2 of the fourth recessed portion R4 may be a width of a portion of the fourth recessed portion R4 having the largest width in the vertical direction (the Z direction).

In some embodiments, the second width W2 of the fourth recessed portion R4 may be greater than a distance between two adjacent nanosheets among the plurality of nanosheets of the first nanosheet stack NSS1. For example, the second width W2 of the fourth recessed portion R4 may be greater than the first distance D1 between two adjacent nanosheets, for example, the first nanosheet N11 and the second nanosheet N12. In other words, the fourth recessed portion R4 may include a portion that is not between two adjacent nanosheets. For example, the fourth recessed portion R4 may include a portion overlapping two adjacent nanosheets in the second horizontal direction (the Y direction).

In some embodiments, the sub-portion 151_S of the first gate dielectric film 151 and/or the first protruding portion 161_P of the first gate line 161, which are in the fourth recessed portion R4, may each include a portion that is not between two adjacent nanosheets. For example, the sub-portion 151_S of the first gate dielectric film 151 and the first protruding portion 161_P of the first gate line 161 may each include a portion overlapping two adjacent nanosheets in the second horizontal direction (the Y direction).

Herein, the shape of the first protruding portion 161_P of the first gate line 161 of the integrated circuit device 102 is not limited to that shown in FIG. 5.

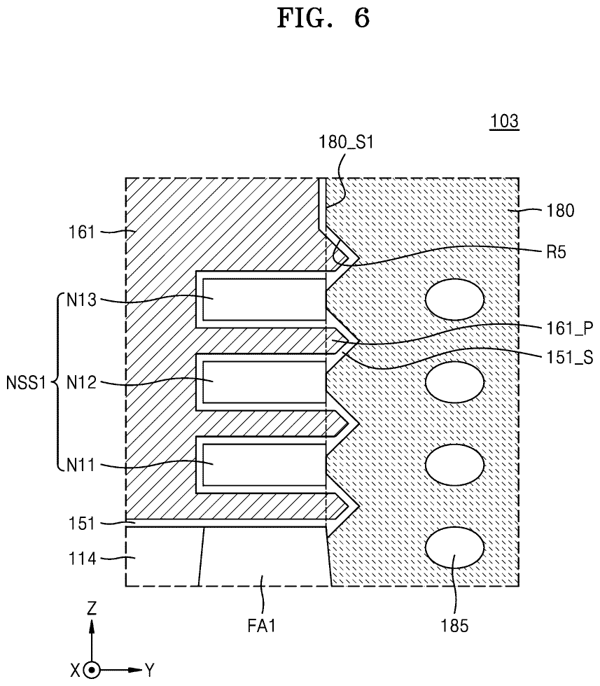

Referring to FIG. 6, the integrated circuit device 103 may include the vertical structure 180 in contact with the plurality of nanosheets. The vertical structure 180 may include one or more air spaces 185 therein. The vertical structure 180 may include a fifth recessed portion R5 on a side wall thereof facing the plurality of nanosheets.

In some embodiments, the fifth recessed portion R5 of the integrated circuit device 103 may include an opening and two side walls that are not parallel to each other. For example, the fifth recessed portion R5 may have a triangular shape. Accordingly, the first protruding portion 161_P of the first gate line 161 in the fifth recessed portion R5 may have a triangular shape.

In some embodiments, a width of the fifth recessed portion R5 of the integrated circuit device 103, at its widest point in the vertical direction (the Z direction), may be greater than a distance between two adjacent nanosheets among the plurality of nanosheets of the first nanosheet stack NSS1. For example, the width of the fifth recessed portion R5 may be greater than a distance between two adjacent nanosheets, for example, the first nanosheet N11 and the second nanosheet N12. In other words, the fifth recessed portion R5 may include a portion that is not between two adjacent nanosheets. For example, the fifth recessed portion R5 may include a portion overlapping two adjacent nanosheets (for example, at least portions of the two adjacent nanosheets) in the second horizontal direction (the Y direction).

In some embodiments, the sub-portion 151_S of the first gate dielectric film 151, which is in the fifth recessed portion R5, may include a portion that is not between two adjacent nanosheets, and the first protruding portion 161_P of the first gate line 161, which is in the fifth recessed portion R5, may not include a portion that is not between two adjacent nanosheets. For example, the sub-portion 151_S of the first gate dielectric film 151 may include a portion overlapping two adjacent nanosheets in the second horizontal direction (the Y direction), and the first protruding portion 161_P of the first gate line 161 may not include a portion overlapping two adjacent nanosheets in the second horizontal direction (the Y direction).

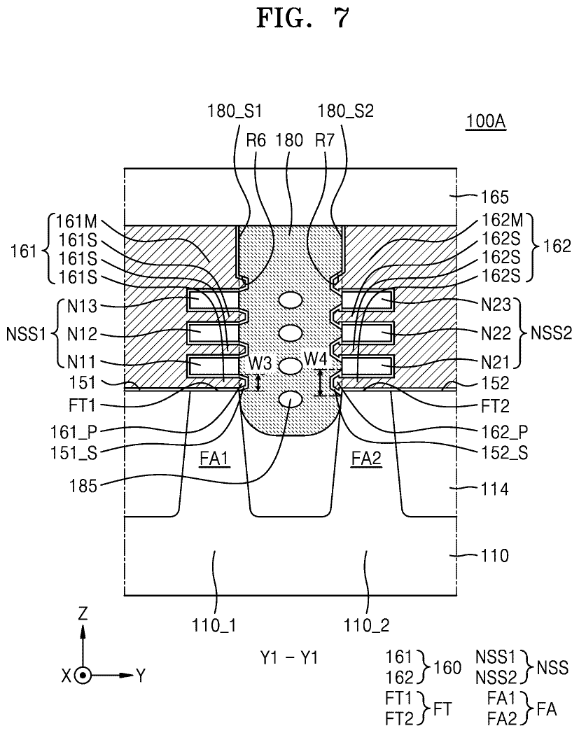

FIG. 7 is a schematic cross-sectional view of an integrated circuit device 100A according to embodiments. Hereinafter, the differences from the integrated circuit device 100 described with reference to FIGS. 1, 2A, 2B, and 3 are mainly described.

Referring to FIG. 7, the integrated circuit device 100A may include the substrate 110 including the first region 110_1 and the second region 1102, the first fin-type active region FA1 extending in the first horizontal direction (the X direction) on the first region 110_1, and the second fin-type active region FA2 extending in the first horizontal direction (the X direction) on the second region 110_2.

In some embodiments, the first gate line 161 extending in the second horizontal direction (the Y direction) may be arranged above the first fin-type active region FA1, and the second gate line 162 extending in the second horizontal direction (the Y direction) may be arranged above the second fin-type active region FA2. The vertical structure 180 may be arranged between the first gate line 161 and the second gate line 162. One or more air spaces 185 may be arranged in the vertical structure 180.

In some embodiments, the vertical structure 180 may include the first side wall 180_S1 facing the first gate line 161, and the second side wall 180_S2 facing the second gate line 162. The vertical structure 180 may include a sixth recessed portion R6 on the first side wall 180_S1 and a seventh recessed portion R7 on the second side wall 180_S2.

In some embodiments, a width of the sixth recessed portion R6 in the vertical direction (the Z direction) may be different from a width of the seventh recessed portion R7 in the vertical direction (the Z direction).

In detail, the sixth recessed portion R6 may have a third width W3 in the vertical direction (the Z direction). An opening of the sixth recessed portion R6 may have the third width W3 in the vertical direction (the Z direction). For example, the third width W3 of the sixth recessed portion R6 may be a width of a portion of the sixth recessed portion R6 having the largest width in the vertical direction (the Z direction).

In some embodiments, the third width W3 of the sixth recessed portion R6 may be equal to or less than a distance between two adjacent nanosheets among the plurality of nanosheets of the first nanosheet stack NSS1. For example, the sixth recessed portion R6 may not overlap two adjacent nanosheets in the second horizontal direction (the Y direction).

In detail, the seventh recessed portion R7 may have a fourth width W4 in the vertical direction (the Z direction). An opening of the seventh recessed portion R7 may have the fourth width W4 in the vertical direction (the Z direction). For example, the fourth width W4 of the seventh recessed portion R7 may be a width of a portion of the seventh recessed portion R7 having the largest width in the vertical direction (the Z direction).

In some embodiments, the fourth width W4 of the seventh recessed portion R7 may be greater than a distance between two adjacent nanosheets among the plurality of nanosheets of the second nanosheet stack NSS2. For example, the seventh recessed portion R7 may include a portion overlapping two adjacent nanosheets in the second horizontal direction (the Y direction).

In some embodiments, the third width W3 of the sixth recessed portion R6 of the integrated circuit device 100A may be less than the fourth width W4 of the seventh recessed portion R7 of the integrated circuit device 100A.

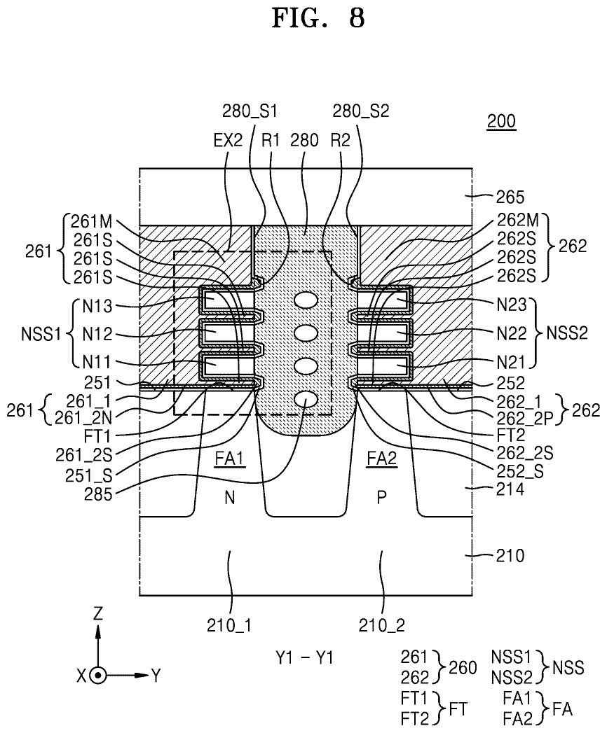

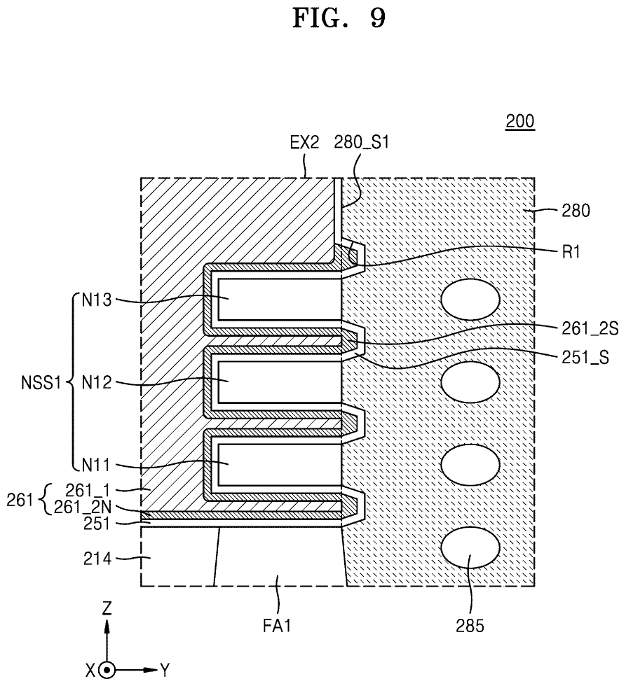

FIG. 8 is a schematic cross-sectional view of an integrated circuit device 200 according to embodiments. FIG. 9 is an enlarged schematic cross-sectional view of region EX2 of the integrated circuit device 200 shown in FIG. 8. Hereinafter, the differences from the integrated circuit device 100 described with reference to FIGS. 1, 2A, 2B, and 3 are mainly described.

Referring to FIGS. 8 and 9, the integrated circuit device 200 may include a substrate 210 including a first region 210_1 and a second region 210_2, the first fin-type active region FA1 extending in the first horizontal direction (the X direction) on the first region 210_1, and the second fin-type active region FA2 extending in the first horizontal direction (the X direction) on the second region 210_2.

In some embodiments, the first region 210_1 and the second region 210_2 of the integrated circuit device 200 may be doped with impurities of different conductivity types. For example, the first region 210_1 of the integrated circuit device 200 may be an n-type field-effect transistor (nFET) region, and the second region 210_2 of the integrated circuit device 200 may be a p-type field-effect transistor (pFET) region. That is, a transistor formed in a portion of the integrated circuit device 200 in which the first fin-type active region FA1 and a first gate line 261 intersect with each other above the first region 2101 may be an nFET, and a transistor formed in a portion of the integrated circuit device 200 in which the second fin-type active region FA2 and a second gate line 262 intersect with each other above the second region 210_2 may be a pFET.

In some embodiments, the first gate line 261 extending in the second horizontal direction (the Y direction) may be arranged above the first fin-type active region FA1, and the second gate line 262 extending in the second horizontal direction (the Y direction) may be arranged above the second fin-type active region FA2.

In some embodiments, the first gate line 261 may include a first main gate portion 261M and a plurality of first sub-gate portions 261S. Likewise, the second gate line 262 may include a second main gate portion 262M and a plurality of second sub-gate portions 262S. A capping insulating pattern 265 may cover a top surface of each of a vertical structure 280 and the gate line 260.

In some embodiments, the first gate line 261 may include a first main metal layer 2611 and a first work function metal layer 261_2N. The first main metal layer 2611 may be arranged on the first work function metal layer 261_2N. The first work function metal layer 261_2N may be arranged between the first main metal layer 261_1 and the first nanosheet stack NSS1 and between the first main metal layer 261_1 and the vertical structure 280. For example, the first work function metal layer 261_2N may be arranged between each of the first nanosheet N11, the second nanosheet N12, and the third nanosheet N13 included in the first nanosheet stack NSS1 and the first main metal layer 261_1 and between the first main metal layer 261_1 and the vertical structure 280.

In some embodiments, the first main gate portion 261M of the first gate line 261 may include a portion in contact with a first gate dielectric film 251. In other words, the first work function metal layer 261_2N may not be arranged between a portion of the first main gate portion 261M of the first gate line 261 and the vertical structure 280.

In some embodiments, the second gate line 262 may include a second main metal layer 262_1 and a second work function metal layer 262_2P. The second main metal layer 262_1 may be arranged on the second work function metal layer 262_2P. The second work function metal layer 262_2P may be arranged between the second main metal layer 2621 and the second nanosheet stack NSS2 and between the second main metal layer 262_1 and the vertical structure 280. For example, the second work function metal layer 262_2P may be arranged between each of the first nanosheet N21, the second nanosheet N22, and the third nanosheet N23 included in the second nanosheet stack NSS2 and the second main metal layer 262_1 and between the second main metal layer 262_1 and the vertical structure 280.

In some embodiments, the first work function metal layer 261_2N of the first gate line 261 and the second work function metal layer 262_2P of the second gate line 262 may include different metal layers. For example, the first work function metal layer 261_2N may include metal for forming an nFET. For example, the second work function metal layer 262_2P may include metal for forming a pFET.

In some embodiments, the second main gate portion 262M of the second gate line 262 may include a portion in contact with a second gate dielectric film 252. In other words, the second work function metal layer 262_2P may not be arranged between a portion of the second main gate portion 262M of the second gate line 262 and the vertical structure 280.

In some embodiments, the first and second gate dielectric films 251 and 252 may be arranged between the nanosheet stack NSS and a gate line 260 and between the gate line 260 and the vertical structure 280. In detail, the first gate dielectric film 251 may be arranged between the first nanosheet stack NSS1 and the first gate line 261 and between the first gate line 261 and the vertical structure 280. For example, the first gate dielectric film 251 may be arranged between the first nanosheet stack NSS1 and the first work function metal layer 261_2N and between the first work function metal layer 261_2N and the vertical structure 280. In detail, the second gate dielectric film 252 may be arranged between the second nanosheet stack NSS2 and the second gate line 262 and between the second gate line 262 and the vertical structure 280. For example, the second gate dielectric film 252 may be arranged between the second nanosheet stack NSS2 and the second work function metal layer 262_2P and between the second work function metal layer 262_2P and the vertical structure 280.

In some embodiments, the vertical structure 280 may be arranged between the first gate line 261 and the second gate line 262. The vertical structure 280 may include a dielectric material. One or more air spaces 285 may be arranged in the vertical structure 280.

In some embodiments, the vertical structure 280 may include a first side wall 280_S1 facing the first gate line 261, and a second side wall 280_S2 facing the second gate line 262. The vertical structure 280 may include the first recessed portion R1 on the first side wall 280_S1 and the second recessed portion R2 on the second side wall 280_S2.

In some embodiments, a portion of the first gate dielectric film 251 and a portion of the first gate line 261 may be in the first recessed portion R1. In detail, the first gate dielectric film 251 may include the sub-portion 251_S in the first recessed portion R1. In detail, a portion 261_2S of the first work function metal layer 261_2N may be in the first recessed portion R1. In some embodiments, the portion 261_2S of the first work function metal layer 261_2N in the first recessed portion R1 may overlap the vertical structure 280 in the vertical direction (the Z direction).

In some embodiments, a portion of the second gate dielectric film 252 and a portion of the second gate line 262 may be in the second recessed portion R2. In detail, the second gate dielectric film 252 may include a sub-portion 252_S in the second recessed portion R2. In detail, a portion 262_2S of the second work function metal layer 262_2P may be in the second recessed portion R2. In some embodiments, the portion 262_2S of the second work function metal layer 262_2P in the second recessed portion R2 may overlap the vertical structure 280 in the vertical direction (the Z direction).

According to the inventive concept, the integrated circuit device 200 including the vertical structure 280 including the first and second recessed portions R1 and R2 on the side walls 280_S1 and 280_S2, respectively, thereof may be provided. As portions of the first and second gate dielectric films 251 and 252 and the first and second gate lines 261 and 262 are respectively arranged in the first and second recessed portions R1 and R2 of the integrated circuit device 200, an effective channel width may increase. In detail, as the portion 261_2S of the first work function metal layer 261_2N and the portion 262_2S of the second work function metal layer 262_2P are respectively arranged in the first and second recessed portions R1 and R2 of the integrated circuit device 200, the effective channel width may increase. That is, according to the inventive concept, the integrated circuit device 200 having improved performance and reliability may be provided.

According to the inventive concept, the integrated circuit device 200 including the vertical structure 280 including one or more air spaces 285 therein may be provided. As the vertical structure 280 includes one or more air spaces 285 therein, parasitic capacitance may be reduced. That is, according to the inventive concept, the integrated circuit device 200 having improved performance and reliability may be provided.

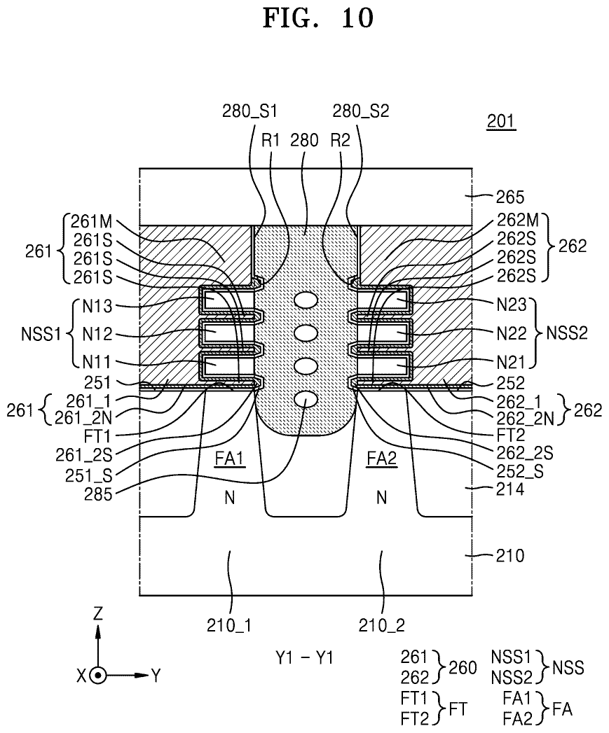

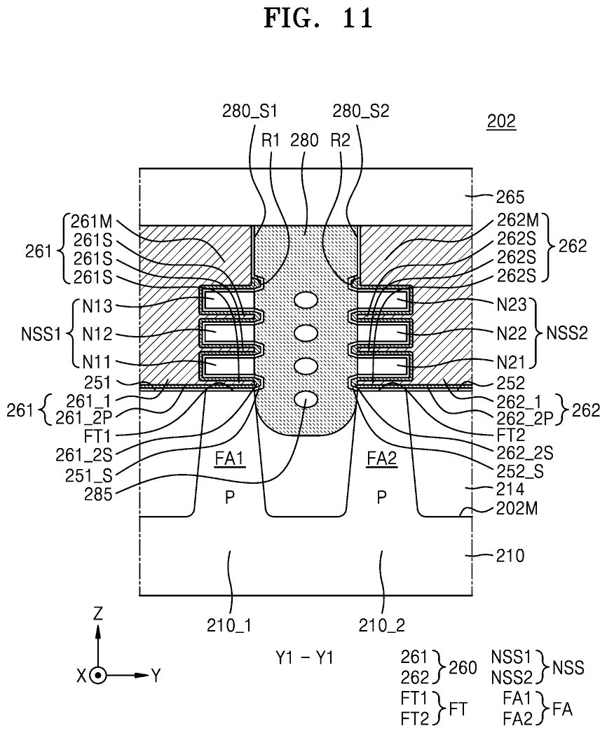

FIGS. 10 and 11 are schematic cross-sectional views of integrated circuit devices 201 and 202, respectively, according to embodiments. Hereinafter, the differences from the integrated circuit device 200 described with reference to FIGS. 8 and 9 are mainly described.

Referring to FIG. 10, the integrated circuit device 201 may include the substrate 210 including the first region 210_1 and the second region 2102, the first fin-type active region FA1 extending in the first horizontal direction (the X direction) on the first region 210_1, and the second fin-type active region FA2 extending in the first horizontal direction (the X direction) on the second region 210_2.

In some embodiments, the first region 210_1 and the second region 210_2 of the integrated circuit device 201 may be doped with impurities of the same conductivity type. For example, the first region 210_1 and the second region 210_2 of the integrated circuit device 201 may each be an nFET region. That is, a transistor formed in a portion of the integrated circuit device 201 in which the first fin-type active region FA1 and the first gate line 261 intersect with each other above the first region 210_1 and a transistor formed in a portion of the integrated circuit device 201 in which the second fin-type active region FA2 and the second gate line 262 intersect with each other above the second region 2102 may each be an nFET.

In some embodiments, the first gate line 261 extending in the second horizontal direction (the Y direction) may be arranged above the first fin-type active region FA1, and the second gate line 262 extending in the second horizontal direction (the Y direction) may be arranged above the second fin-type active region FA2.

In some embodiments, the first gate line 261 may include the first main metal layer 261_1 and the first work function metal layer 261_2N. The second gate line 262 may include the second main metal layer 262_1 and a second work function metal layer 262_2N.

In some embodiments, the first work function metal layer 261_2N of the first gate line 261 and the second work function metal layer 262_2N of the second gate line 262 may include the same metal layer. For example, the first work function metal layer 261_2N and the second work function metal layer 262_2N may each include metal for forming an nFET.

In some embodiments, the vertical structure 280 may be arranged between the first gate line 261 and the second gate line 262. The vertical structure 280 may include an insulating material. One or more air spaces 285 may be arranged in the vertical structure 280.

In some embodiments, the vertical structure 280 may include the first recessed portion R1 on the first side wall 280_S1 and the second recessed portion R2 on the second side wall 280_S2. In some embodiments, the sub-portion 251_S of the first gate dielectric film 251 and a portion of the first gate line 261 may be in the first recessed portion R1. In detail, the portion 261_2S of the first work function metal layer 261_2N may be in the first recessed portion R1. In some embodiments, the sub-portion 252_S of the second gate dielectric film 252 and a portion of the second gate line 262 may be in the second recessed portion R2. In detail, the portion 262_2S of the second work function metal layer 262_2N may be in the second recessed portion R2.

Referring to FIG. 11, the integrated circuit device 202 may include the substrate 210 including the first region 210_1 and the second region 2102, the first fin-type active region FA1 extending in the first horizontal direction (the X direction) on the first region 210_1, and the second fin-type active region FA2 extending in the first horizontal direction (the X direction) on the second region 210_2.

In some embodiments, the first region 210_1 and the second region 210_2 of the integrated circuit device 202 may be doped with impurities of the same conductivity type. For example, the first region 210_1 and the second region 210_2 of the integrated circuit device 202 may each be a pFET region. That is, a transistor formed in a portion of the integrated circuit device 202 in which the first fin-type active region FA1 and the first gate line 261 intersect with each other above the first region 210_1 and a transistor formed in a portion of the integrated circuit device 202 in which the second fin-type active region FA2 and the second gate line 262 intersect with each other above the second region 2102 may each be a pFET.

In some embodiments, the first gate line 261 extending in the second horizontal direction (the Y direction) may be arranged above the first fin-type active region FA1, and the second gate line 262 extending in the second horizontal direction (the Y direction) may be arranged above the second fin-type active region FA2.

In some embodiments, the first gate line 261 may include the first main metal layer 261_1 and a first work function metal layer 261_2P. The second gate line 262 may include the second main metal layer 262_1 and the second work function metal layer 262_2P.

In some embodiments, the first work function metal layer 261_2P of the first gate line 261 and the second work function metal layer 262_2P of the second gate line 262 may include the same metal layer. For example, the first work function metal layer 261_2P and the second work function metal layer 262_2P may each include metal for forming a pFET.

In some embodiments, the vertical structure 280 may be arranged between the first gate line 261 and the second gate line 262. The vertical structure 280 may include an insulating material. One or more air spaces 285 may be arranged in the vertical structure 280.

In some embodiments, the vertical structure 280 may include the first recessed portion R1 on the first side wall 280_S1 facing the first gate line 261, and the second recessed portion R2 on the second side wall 280_S2 facing the second gate line 262. In some embodiments, the sub-portion 251_S of the first gate dielectric film 251 and a portion of the first gate line 261 may be in the first recessed portion R1. In detail, the portion 261_2S of the first work function metal layer 261_2P may be in the first recessed portion R1. In some embodiments, the sub-portion 252_S of the second gate dielectric film 252 and a portion of the second gate line 262 may be in the second recessed portion R2. In detail, the portion 262_2S of the second work function metal layer 262_2P may be in the second recessed portion R2.

FIGS. 12A to 12F are schematic cross-sectional views illustrating intermediate processes in an example method of manufacturing the integrated circuit device 100, according to one or more embodiments.

Referring to FIG. 12A, a plurality of sacrificial semiconductor layers 104 and a plurality of nanosheet semiconductor layers may be alternately stacked one-by-one on the substrate 110 in the vertical direction (i.e., the Z direction), and then, by etching portions of the plurality of sacrificial semiconductor layers 104, the plurality of nanosheet semiconductor layers, and the substrate 110, a plurality of fin-type active regions FA may be defined in the substrate 110. Thereafter, the device isolation film 114 may be formed to cover a side wall of each of the plurality of fin-type active regions FA.

The plurality of sacrificial semiconductor layers 104 and the plurality of nanosheet semiconductor layers may include semiconductor materials with different etch selectivities. In some embodiments, the plurality of nanosheet semiconductor layers may include a Si layer, and the plurality of sacrificial semiconductor layers 104 may include a SiGe layer. In some embodiments, a Ge content in the plurality of sacrificial semiconductor layers 104 may be constant. The SiGe layer constituting the plurality of sacrificial semiconductor layers 104 may have a constant Ge content selected from a range of about 5 atomic percent (at %) to about 60 at %, for example, about 10 at % to about 40 at %. The Ge content in the SiGe layer constituting the plurality of sacrificial semiconductor layers 104 may be selected in various ways as needed.

Subsequently, by etching a portion of each of the plurality of sacrificial semiconductor layers 104 and the plurality of nanosheet semiconductor layers and a portion of the fin-type active region FA, the plurality of nanosheet semiconductor layers may be divided into a plurality of nanosheet stacks NSS. Thereafter, a portion of the device isolation film 114 between the plurality of fin-type active regions FA may be etched to form a trench.

Referring to FIG. 12B, a semiconductor material may be epitaxially grown from side walls of the plurality of sacrificial semiconductor layers 104 exposed through the trench. As a result, a plurality of dummy blocks 105 may be formed to respectively protrude from the side walls of the plurality of sacrificial semiconductor layers 104 in the second horizontal direction (the Y direction).

In some embodiments, a Si source and a Ge source may be used to form the plurality of dummy blocks 105. The plurality of dummy blocks 105 may include a SiGe layer.

In some embodiments, a width of the plurality of dummy blocks 105 in the vertical direction (the Z direction) may be less than or equal to a width of the plurality of sacrificial semiconductor layers 104 in the vertical direction (the Z direction).

In some other embodiments, not explicitly shown, the width of each of the plurality of dummy blocks 105 in the vertical direction (the Z direction) may be greater than the width of each of the plurality of sacrificial semiconductor layers 104 in the vertical direction (the Z direction). In this case, the integrated circuit device 102 described with reference to FIG. 5 may be manufactured.

Referring to FIG. 12C, the vertical structure 180 may be formed in the trench. In detail, the trench may be filled with a dielectric material to form the vertical structure 180 arranged between the first fin-type active region FA1 and the second fin-type active region FA2 and between the first nanosheet stack NSS1 and the second nanosheet stack NSS2.

In some embodiments, in the process of forming the vertical structure 180, due to the presence of the plurality of dummy blocks 105, one or more air spaces 185 may be formed in the vertical structure 180. In detail, due to the presence of the plurality of dummy blocks 105, the dielectric material may be folded to form one or more air spaces 185 in the vertical structure 180. The one or more air spaces 185 may be formed to overlap the plurality of nanosheets in the second horizontal direction (the Y direction).

Referring to FIG. 12D, the plurality of sacrificial semiconductor layers 104 and the plurality of dummy blocks 105 may be removed to expose the plurality of nanosheet stacks NSS. In detail, the plurality of nanosheets included in the plurality of nanosheet stacks NSS, the fin top surface FT, and two side walls (i.e., opposing sidewalls) of the vertical structure 180 may be exposed.

The first recessed portion R1 and the second recessed portion R2 may be formed on the exposed two side walls of the vertical structure 180. The first recessed portion R1 and the second recessed portion R2 may be formed as some regions of the trench are not filled with the dielectric material due to the plurality of dummy blocks 105 (see FIG. 12C).

Referring to FIG. 12E, the first and second gate dielectric films 151 and 152 may be formed to cover the side walls of the vertical structure 180 and the plurality of nanosheet stacks NSS.

In detail, the first gate dielectric film 151 may be formed on top surfaces, bottom surfaces, and side walls of the first to third nanosheets N11, N12, and N13 included in the first nanosheet stack NSS1, the first fin top surface FT1, the device isolation film 114, and the side wall of the vertical structure 180, including exposed surfaces of the first recessed portions R1. In detail, the second gate dielectric film 152 may be formed on top surfaces, bottom surfaces, and side walls of the first to third nanosheets N21, N22, and N23 included in the second nanosheet stack NSS2, the second fin top surface FT2, the device isolation film 114, and the side wall of the vertical structure 180, including exposed surfaces of the second recessed portions R2.

As described above, the first and second gate dielectric films 151 and 152 may include sub-portions respectively arranged in the first recessed portion R1 and the second recessed portion R2. For example, the first gate dielectric film 151 may include the sub-portion 151_S arranged in the first recessed portion R1. The second gate dielectric film 152 may include the sub-portion 152_S arranged in the second recessed portion R2.

Referring to FIG. 12F, the gate line 160 may be formed on the first and second gate dielectric films 151 and 152. In detail, the first gate line 161 may be formed above the first fin-type active region FA1, and the second gate line 162 may be formed above the second fin-type active region FA2.

By performing the manufacturing method of FIGS. 12A to 12F, the integrated circuit device 100 may be manufactured (see FIGS. 1 through 3).

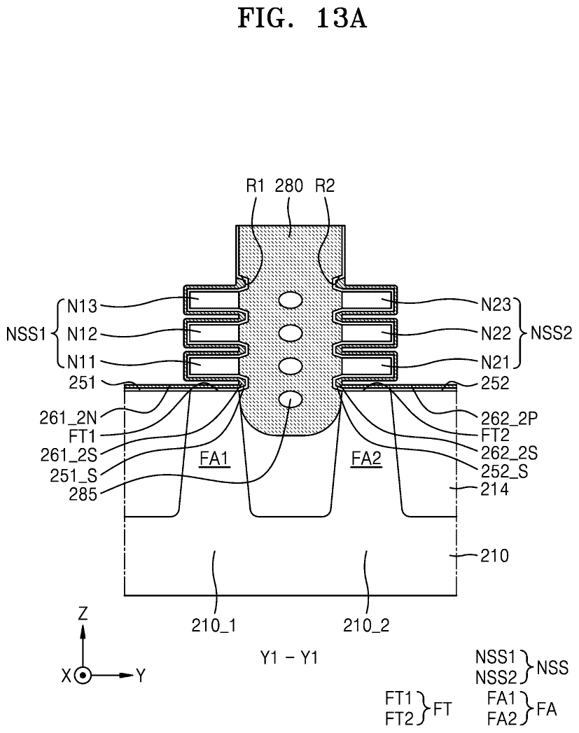

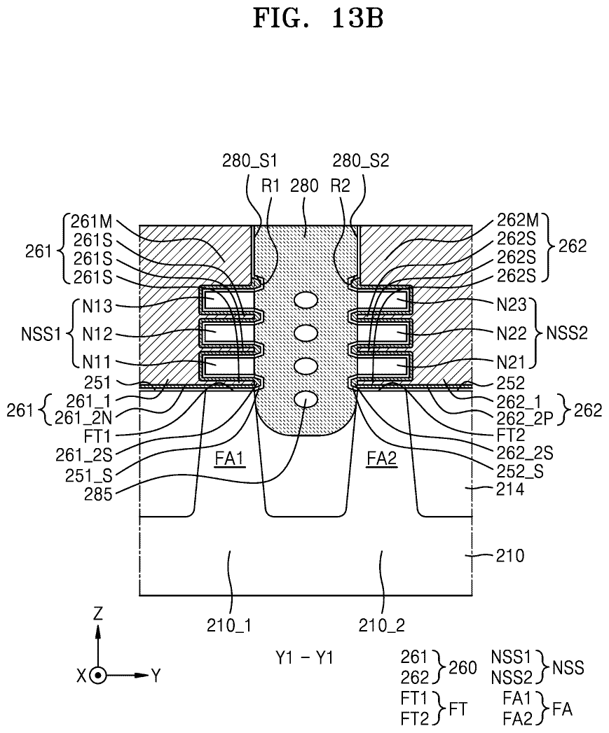

FIGS. 13A and 13B are schematic cross-sectional views illustrating intermediate processes in an example method of manufacturing the integrated circuit device 200 (see FIG. 8), according to embodiments. In detail, the example method shown in FIGS. 13A and 13B for manufacturing the integrated circuit device 200 (FIG. 8) may be performed subsequent to the process described with reference to FIG. 12E, according to some embodiments.

Referring to FIG. 13A, a first work function metal layer 261_2N and a second work function metal layer 262_2P may be respectively formed on the first and second gate dielectric films 251 and 252. In detail, above the first fin-type active region FA1, the first work function metal layer 261_2N may be formed on the first gate dielectric film 251, and above the second fin-type active region FA2, the second work function metal layer 262_2P may be formed on the second gate dielectric film 252.

In detail, the first work function metal layer 261_2N may be formed on the top surfaces, bottom surfaces, and side walls of the first to third nanosheets N11, N12, and N13 included in the first nanosheet stack NSS1, the first fin top surface FT1, a device isolation film 214, and the side wall of the vertical structure 280. In detail, the second work function metal layer 262_2P may be formed on the top surfaces, bottom surfaces, and side walls of the first to third nanosheets N21, N22, and N23 included in the second nanosheet stack NSS2, the second fin top surface FT2, the device isolation film 214, and the side wall of the vertical structure 280.

As described above, the first work function metal layer 261_2N and the second work function metal layer 262_2P may include portions respectively arranged in the first recessed portion R1 and the second recessed portion R2. For example, the first work function metal layer 261_2N may include the portion 261_2S in the first recessed portion R1. The second work function metal layer 262_2P may include the portion 262_2S in the second recessed portion R2.

Referring to FIG. 13B, the first main metal layer 261_1 and the second main metal layer 262_1 may be respectively formed on the first work function metal layer 261_2N and the second work function metal layer 262_2P. In detail, by forming the first main metal layer 261_1 on the first work function metal layer 261_2N, the first gate line 261 may be formed. By forming the second main metal layer 262_1 on the second work function metal layer 262_2P, the second gate line 262 may be formed.

By performing the manufacturing method of FIGS. 13A and 13B, the integrated circuit device 200 (see FIG. 8) may be manufactured.

According to the inventive concept, an integrated circuit device having improved performance and reliability may be provided.

While the inventive concept has been particularly shown and described with reference to embodiments thereof, it will be understood that various changes in form and details may be made therein without departing from the spirit and scope of the following claims.

What is claimed is:

1. An integrated circuit device, comprising:
a fin-type active region extending in a first horizontal direction on a substrate, the first horizontal direction being parallel to an upper surface of the substrate;
a nanosheet stack comprising a plurality of nanosheets on the fin-type active region;
a gate line extending around each of the plurality of nanosheets on the fin-type active region and extending in a second horizontal direction parallel to the upper surface of the substrate and intersecting with the first horizontal direction; and
a vertical structure at least partially overlapping the gate line in the second horizontal direction and comprising a side wall in contact with each of the plurality of nanosheets,
wherein the vertical structure further comprises a recessed portion on the side wall thereof.

2. The integrated circuit device of claim 1, wherein the gate line comprises a protruding portion extending into the recessed portion.

3. The integrated circuit device of claim 2, wherein the protruding portion at least partially overlaps the vertical structure in a vertical direction perpendicular to the upper surface of the substrate.

4. The integrated circuit device of claim 1, wherein the recessed portion comprises a portion overlapping at least portions of the plurality of nanosheets in the second horizontal direction.

5. The integrated circuit device of claim 1, wherein the gate line comprises:
a main metal layer; and
a work function metal layer between the main metal layer and each of the plurality of nanosheets and between the main metal layer and the vertical structure,
wherein the work function metal layer comprises a portion in the recessed portion.

6. The integrated circuit device of claim 1, wherein the vertical structure further comprises an air space therein.

7. The integrated circuit device of claim 6, wherein the air space overlaps at least portions of the plurality of nanosheets in the second horizontal direction.

8. An integrated circuit device, comprising:
a substrate comprising a first region and a second region;
a first fin-type active region extending in a first horizontal direction parallel to an upper surface of the substrate on the first region;
a second fin-type active region extending in the first horizontal direction on the second region and spaced apart from the first fin-type active region in a second horizontal direction parallel to the upper surface of the substrate and intersecting with the first horizontal direction;
a plurality of first nanosheets facing a top surface of the first fin-type active region and spaced apart from the top surface of the first fin-type active region in a vertical direction perpendicular to the upper surface of the substrate;
a plurality of second nanosheets facing a top surface of the second fin-type active region and spaced apart from the top surface of the second fin-type active region in the vertical direction;
a first gate line extending around each of the plurality of first nanosheets on the first fin-type active region and extending in the second horizontal direction;
a second gate line extending around each of the plurality of second nanosheets on the second fin-type active region and extending in the second horizontal direction; and
a vertical structure between the first gate line and the second gate line and having two side walls respectively in contact with each of the plurality of first nanosheets and each of the plurality of second nanosheets,
wherein the two side walls of the vertical structure each comprise a recessed portion extending into the vertical structure, and
the first gate line and the second gate line each comprise a protruding portion extending into the recessed portion.

9. The integrated circuit device of claim 8, wherein the first gate line comprises:
a first main metal layer; and
a first work function metal layer between the first main metal layer and each of the plurality of first nanosheets and between the first main metal layer and the vertical structure, and
the second gate line comprises:
a second main metal layer; and
a second work function metal layer between the second main metal layer and each of the plurality of second nanosheets and between the second main metal layer and the vertical structure,
wherein each of the first work function metal layer and the second work function metal layer comprises a portion in the recessed portion.

10. The integrated circuit device of claim 8, wherein the vertical structure further comprises an air space therein.

11. The integrated circuit device of claim 10, wherein the air space at least partially overlaps at least portions of the first and second plurality of nanosheets in the second horizontal direction.

12. The integrated circuit device of claim 8, wherein the recessed portion comprises a portion at least partially overlapping at least portions of the first and second plurality of nanosheets in the second horizontal direction.

13. The integrated circuit device of claim 8, further comprising:
a first gate dielectric film between the first gate line and the plurality of first nanosheets and between the first gate line and the vertical structure; and
a second gate dielectric film between the second gate line and the plurality of second nanosheets and between the second gate line and the vertical structure,
wherein each of the first gate dielectric film and the second gate dielectric film comprises a sub-portion in the recessed portion.

14. The integrated circuit device of claim 13, wherein the sub-portion of each of the first gate dielectric film and the second gate dielectric film at least partially overlaps the vertical structure in the vertical direction.

15. The integrated circuit device of claim 8, wherein the two side walls of the vertical structure comprise a first side wall and a second side wall, the first side wall facing the first gate line, and the second side wall facing the second gate line,
wherein the first side wall comprises a first recessed portion,
the second side wall comprises a second recessed portion, and
a first width of the first recessed portion in the vertical direction is different from a second width of the second recessed portion in the vertical direction.

16. The integrated circuit device of claim 8, wherein the first fin-type active region and the second fin-type active region are of different conductivity types, and
the vertical structure comprises a dielectric material.

17. An integrated circuit device, comprising:
a substrate comprising a first region and a second region;
a first fin-type active region extending in a first horizontal direction, parallel to an upper surface of the substrate, on the first region;
a second fin-type active region extending in the first horizontal direction on the second region and spaced apart from the first fin-type active region in a second horizontal direction parallel to the upper surface of the substrate and intersecting with the first horizontal direction;
a first nanosheet stack comprising a plurality of first nanosheets at different levels in a vertical direction perpendicular to the upper surface of the substrate, relative to the upper surface of the substrate as a reference layer, each of the plurality of first nanosheets facing a top surface of the first fin-type active region and spaced apart from the top surface of the first fin-type active region in the vertical direction;
a second nanosheet stack comprising a plurality of second nanosheets at different levels in the vertical direction relative to the upper surface of the substrate, each of the plurality of second nanosheets facing a top surface of the second fin-type active region and spaced apart from the top surface of the second fin-type active region in the vertical direction;
a first gate line extending around each of the plurality of first nanosheets on the first fin-type active region and extending in the second horizontal direction;
a second gate line extending around each of the plurality of second nanosheets on the second fin-type active region and extending in the second horizontal direction;
a vertical structure between the first gate line and the second gate line and in contact with each of the plurality of first nanosheets and each of the plurality of second nanosheets;
a first source/drain region adjacent to the first gate line and in contact with each of the plurality of first nanosheets; and
a second source/drain region adjacent to the second gate line and in contact with each of the plurality of second nanosheets,
wherein the first gate line comprises:
a first main metal layer; and
a first work function metal layer between the first main metal layer and each of the plurality of first nanosheets and between the first main metal layer and the vertical structure,
the second gate line comprises:
a second main metal layer; and
a second work function metal layer between the second main metal layer and each of the plurality of second nanosheets and between the second main metal layer and the vertical structure,
the vertical structure comprises an air space therein,
the vertical structure further comprises a first side wall and a second side wall, the first side wall facing the first gate line, and the second side wall facing the second gate line,
the first side wall comprises a first recessed portion,
the second side wall comprises a second recessed portion,
the first work function metal layer comprises a portion in the first recessed portion and at least partially overlapping the vertical structure in the vertical direction, and
the second work function metal layer comprises a portion in the second recessed portion and at least partially overlapping the vertical structure in the vertical direction.

18. The integrated circuit device of claim 17, wherein both the first region and the second region comprise n-type field-effect transistor (nFET) regions or p-type field-effect transistor (pFET) regions, and
the vertical structure comprises an insulating material.

19. The integrated circuit device of claim 17, wherein the first region comprises an n-type field-effect transistor (nFET) region,
the second region comprises a p-type field-effect transistor (pFET) region,
the vertical structure comprises a dielectric material,
the first work function metal layer comprises an n-type metal layer, and
the second work function metal layer comprises a p-type metal layer.

20. The integrated circuit device of claim 17, wherein the air space overlaps at least portions of each of the plurality of first nanosheets and each of the plurality of second nanosheets in the second horizontal direction.
